(19) United States
(12) Patent Application Publication
(10) Pub. No.: US 2025/0112206 A1
(43) Pub. Date: Apr. 3, 2025

(54) DIE PLACEMENT WITHIN A FORMED CAVITY ON A REDISTRIBUTION LAYER

(71) Applicant: Intel Corporation, Santa Clara, CA (US)

(72) Inventors: Eduardo DE MESA, Munich (DE); Abdallah BACHA, Munich (DE); Jan PROSCHWITZ, Riesa (DE); Georg SEIDEMANN, Landshut (DE)

(21) Appl. No.: 18/374,943

(22) Filed: Sep. 29, 2023

(51) Int. Cl. H01L 25/065; H01L 23/00; H01L 23/053; H01L 23/538; H01L 25/00; H10B 80/00

(52) U.S. Cl. CPC H01L 25/0655; H01L 23/053; H01L 23/5383; H01L 24/16; H01L 24/32; H01L 24/73; H01L 25/50; H10B 80/00; H01L 2224/16225; H01L 2224/32225; H01L 2224/73204

(57) ABSTRACT

Embodiments herein relate to systems, apparatuses, techniques or processes for forming a package that includes a mold compound on a first surface of a redistribution layer, where the mold compound includes one or more cavities, and wherein one or more dies are placed within the cavities. In embodiments, one or more dies may be placed on the second surface of the redistribution layer. In embodiments, the dies, mold compound, and redistribution layer may have different coefficients of thermal expansion, in order to reduce warpage of the package during manufacture and operation. Other embodiments may be described and/or claimed.

Embodiments of the present disclosure generally relate to package assemblies, and in particular package assemblies that include dies.

### BACKGROUND

Continued reduction in end product size of mobile electronic devices such as smart phones and ultrabooks is a driving force for the development of reduced size system in package components with increased component quality.

### BRIEF DESCRIPTION OF THE DRAWINGS

FIG. 1 illustrates a perspective view, top-down view, and side view of one or more cavities within a mold compound on a redistribution layer (RDL) in accordance with various embodiments.

FIG. 2 illustrates a side view of a package that includes a RDL, dies within cavities in a mold compound on in a RDL, with chips on the opposite side of the RDL, in accordance with various embodiments.

FIGS. 3A-3I illustrate side views of stages in a manufacturing process for placing dies within a formed cavity on a RDL, in accordance with various embodiments.

FIGS. 4A-4I illustrate side views of stages in another manufacturing process for placing dies within a formed cavity on a RDL, in accordance with various embodiments.

FIGS. 5A-5H illustrate side views of stages in another manufacturing process for placing dies within a formed cavity on a RDL, in accordance with various embodiments.

FIG. 6 illustrates an example of a process for creating a package that includes a RDL that have dies within cavities formed on the mold compound on the RDL, in accordance with various embodiments.

FIG. 7 schematically illustrates a computing device, in accordance with embodiments.

### DETAILED DESCRIPTION

Embodiments of the present disclosure may generally relate to systems, apparatus, techniques and/or processes directed to placing a mold compound on a RDL, where the mold compound includes cavities, and where dies are placed in the cavities. In embodiments, the surface of the RDL opposite the mold compound may include one or more dies. In some embodiments, the dies within the mold compound may be high bandwidth memory dies (HBM), and the dies on the RDL opposite the mold compound may be one or more compute/network dies that may be electrically coupled with the HBM through the RDL.

In embodiments, these techniques may be used to design packages to facilitate reduction in peak stress areas within the package and to facilitate greater package yield. In embodiments, positions of the cavities within the mold compound, as well as the characteristic of the dies placed within the cavities, may also be used to facilitate reduction in stress areas within the package, and may also result in a flatter package. In embodiments, these characteristics may include having a different coefficient of thermal expansion (CTE).

Legacy implementations are increasingly moving away from monolithic integration to disaggregation techniques when constructing semiconductor packages. For example, smaller dies may be used and may be connected with bridges within the package. These approaches tend to lead to packages with a greater footprint, and therefore they may create additional challenges during production and assembly. In particular, thermal mechanical stress during the lifetime of the package, and also resulting warpage caused by different CTE material combinations, for example silicon dies, dielectric materials, and substrates, may result in fails within interfaces. Countermeasures using the techniques described herein may reduce the stresses and these failures, and as a result facilitate a more robust package.

In some legacy implementations, large packages may be built with chiplets using multiple dies to reduce cost and footprint, in combination with a silicon interposer layer, a RDL interposer, and/or substrates. In these techniques, there may be rigidness as a result of the buildups that may be sensitive to warpage at later assembly processes, thus increasing the risk to cracks during assembly as well as during lifetime performance of the package. Legacy implementations to address these issues include using thicker dies, larger pads and/or bump dimensions.

Other legacy efforts may involve using expensive non-reusable carrier systems in order to reduce warpage during manufacture. Other efforts may include optimizing the stack up of materials to improve the total CTE during manufacturing. These legacy optimizations techniques however, may incur high costs and still have limitations regarding the warpage of buildups. This in turn may prevent the increased in size of packages, or may prevent proper functioning within harsher environmental situations.

In embodiments described herein, the rigidness and/or stability of mold compounds and substrates in a package may be modified and/or controlled using a variety of cavity placements and implementing structures within the cavities of a mold compound, as well as material variations of the structures, for warpage control. In embodiments, warpage measurement and process temperature may be controlled for the complete package stack up.

In embodiments, these techniques may have the advantage of reducing rigidness of the package, and as a result, the package may be able to better adapt to warpage during the assembly process. In addition, these techniques may result in lower internal mechanical stress during operation, higher assembly yield at a reduced warpage, and may also improve package robustness and performance during the lifetime of the package.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various Figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

Various embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

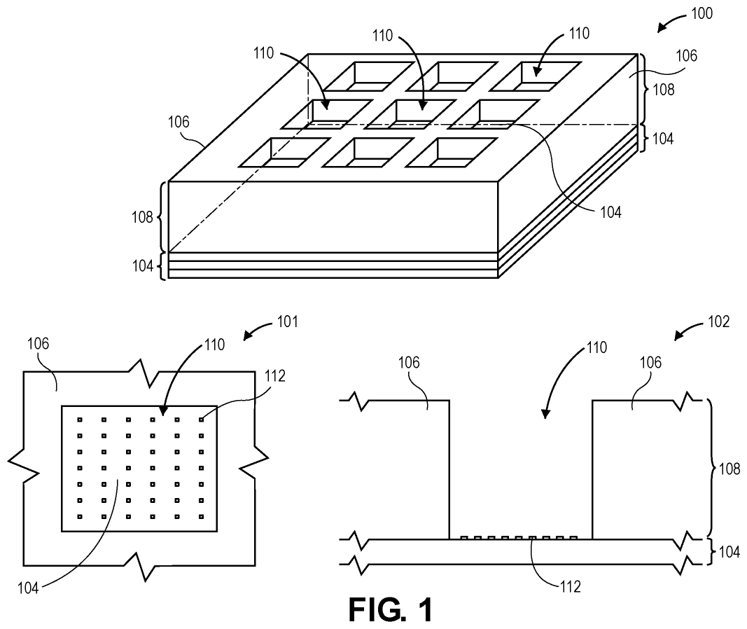

FIG. 1 illustrates a perspective view, top-down view, and side view of one or more cavities within a mold compound on a RDL in accordance with various embodiments. Package 100 shows a perspective view with RDL 104, that may include multiple layers, with a mold compound 106 on the RDL 104 that may include a plurality of cavities 110 within the mold compound 106. In embodiments, the cavities 110 in combination with the mold compound 106 form cavity layer 108. In other embodiments, the RDL 104 may be some other layer, for example a substrate, or some other layer that may be within a package, and the mold compound 106 may be some other layer, for example a substrate, a layer of silicon, or some other material. In embodiments, the mold compound 106 may be across all or part of a surface of the RDL 104, and the cavities 110 may be formed subsequently after the mold compound 106 has been placed.

As shown in package 100, the cavities 110 may be formed using molding laser ablation, as described below, or may be formed using laser grooving. In embodiments, the cavities 110 may be any size or shape, for example trenches that may extend from one side of the package 100 to the other. In embodiments, the cavities 110 may have sides that are different shape or a different thickness. In some embodiments, mold compound 106 may have different thicknesses depending on where the mold compound 106 is above the RDL 104. In embodiments, sides of the cavities 110 may be planar.

As discussed further below, the choice of the mold compound 106, the composition/design of the RDL 104, the positioning of the cavities 110, and the materials inserted into the cavities (discussed further below), may be chosen to reduce the rigidity of the package 100, and as a result reduce warpage of the package 100 during assembly, board assembly, and/or operation. In addition, in embodiments the materials may have different CTE values, which may also be chosen to reduce the warpage of the package.

In embodiments, as a result of these techniques the overall structure the package 100 may be more flexible, the built-in stress and risk of package cracks be reduced. Due to the resulting lower warpage of the package 100, the stress on solder balls (not shown) as well as the risk of solder ball fatigue may be substantially reduced. This a result in increased robustness of the package 100 during its lifetime.

Diagram 101 shows a top-down view of a cavity 110 of package 100. The cavity 110 is surrounded by mold compound 106, with the RDL 104 visible at the bottom. In embodiments, there may be bumps 112, which may in some embodiments be some form of electrical connector, to which a die (not shown but discussed below) may be inserted within the cavity 110 and electrically coupled with the bumps 112 in order to electrically couple the die with the RDL 104.

Diagram 102 shows a cross-section side view of diagram 101, with the cavity 110 surrounded by mold compound 106 that form cavity layer 108. In embodiments, the bumps 112 may be on a surface of the RDL 104, and may electrically couple with the RDL 104.

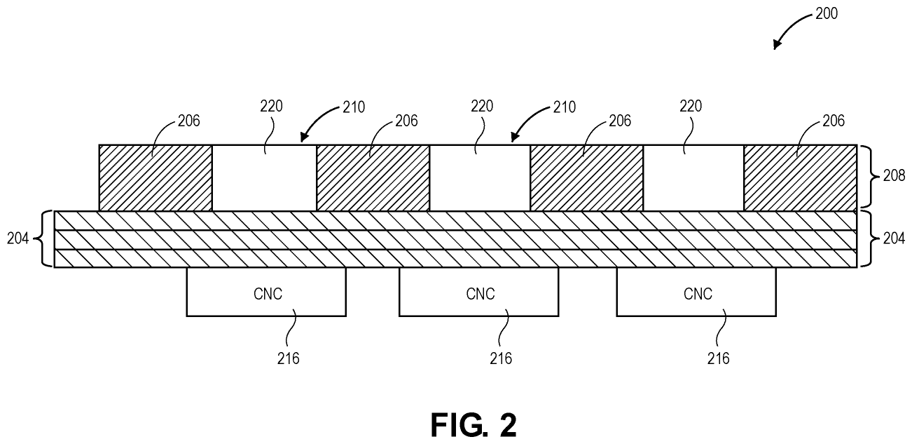

FIG. 2 illustrates a side view of a package that includes a RDL, dies within cavities in a mold compound on in a RDL, with chips on the opposite side of the RDL, in accordance with various embodiments. Package 200, which may be similar to package 100 of FIG. 1, is a cross-section side view that includes RDL 204 and a cavity layer 208, with mold compound 206 that surrounds cavities 210. In embodiments, dies 220 may be placed within the cavities 210, and on the RDL 204. In embodiments, some of the dies 220 may be HBM. In embodiments, some of the dies 220 may be silicon dies, or may be some other material placed within the cavities 210. In embodiments, the RDL 204, cavity layer 208, mold compound 206, and cavities 210 may be similar to RDL 104, cavity layer 108, mold compound 106, and cavities 110 of FIG. 1.

In embodiments, on the bottom of the RDL 204 may be a plurality of dies 216, which may be referred to as chips. In embodiments, the dies 216 each may be one or more dies that is part of a die complex which may include, for example, compute dies, network dies, and/or bridges that may electrically and/or physically couple these dies. In other embodiments the dies 216 may be some other type of die, or may be some other structure that may be part of the package 200. In embodiments, the dies 220 may be electrically coupled with the dies 216 through the RDL 204.

In embodiments, the location of the dies 216 on the bottom of the RDL 204, the location and size of the cavities 210 within the mold compound 206 within the cavity layer 208 on the top of the RDL 204, and the location of the dies 220 within the cavities 210, may each be chosen such that the placement minimizes warpage during assembly and operation of the package 200. In embodiments, a CTE of each of the respective components may be selected to minimize warpage for the package 200.

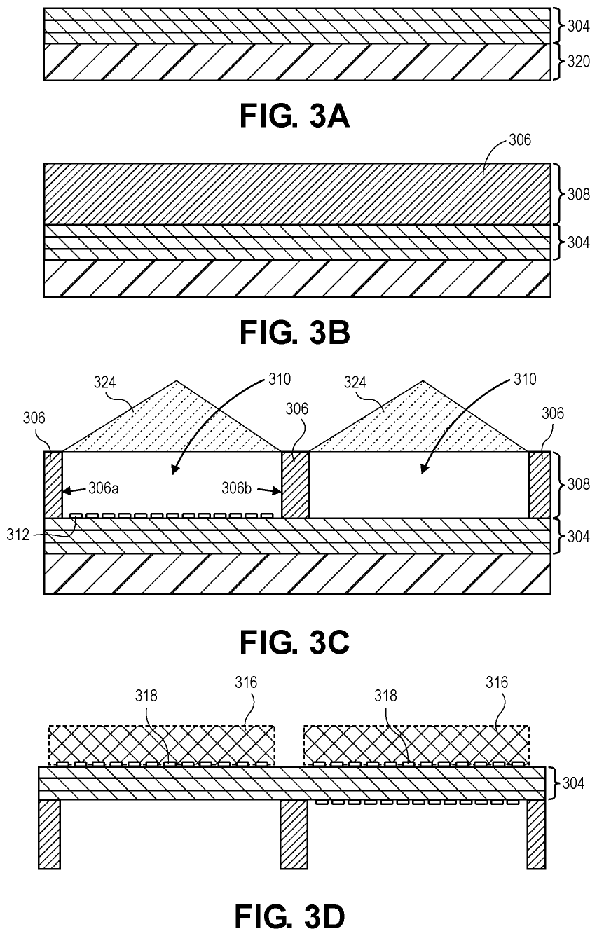

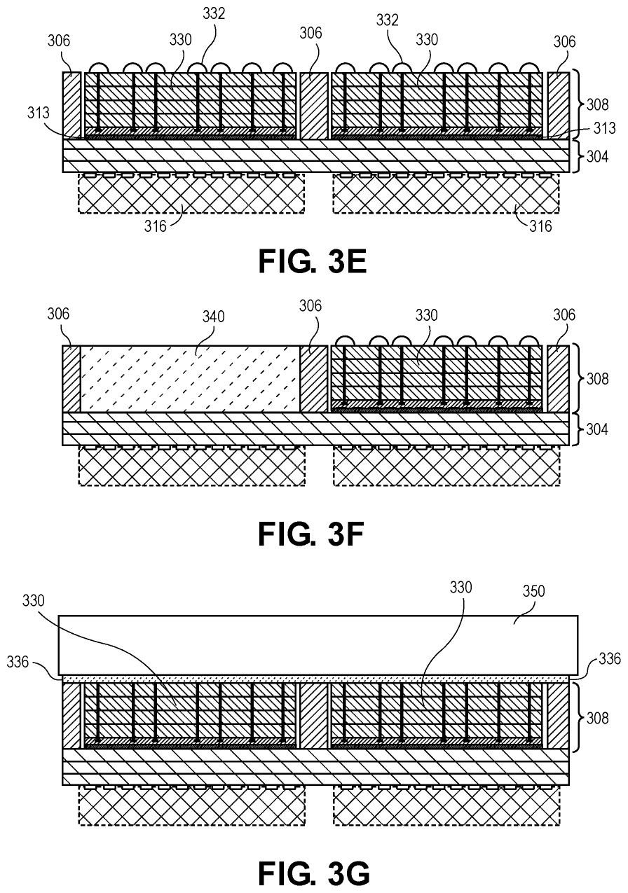

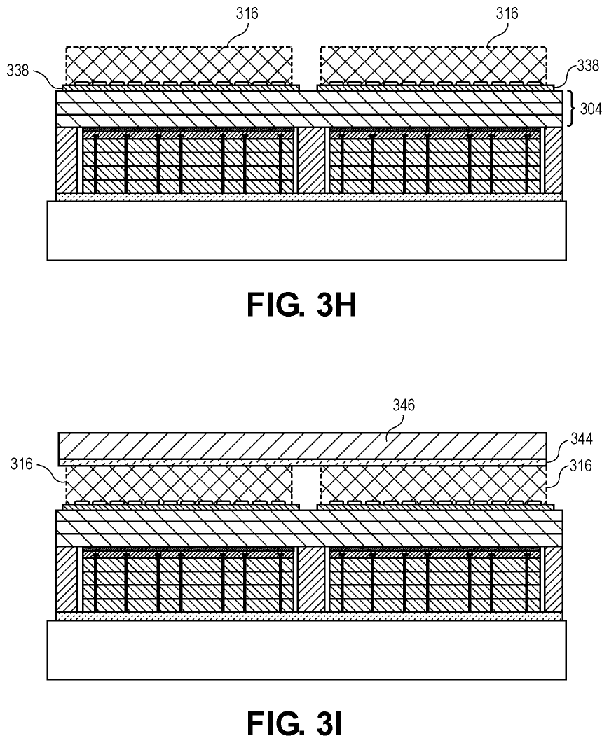

FIGS. 3A-3I illustrate side views of stages in a manufacturing process for placing dies within a formed cavity on a RDL, in accordance with various embodiments. In embodiments, FIGS. 3A-3I may illustrate a first mold compound ablation process. FIG. 3A shows a cross-section side view of a stage in the manufacturing process where a carrier 320 may be provided. In embodiments, the carrier 320 may be a glass carrier. In embodiments, a RDL 304 may be placed on the carrier 320. In embodiments, the RDL 304 may include a plurality of layers, as well as traces and/or vias (not shown) within the RDL 304.

FIG. 3B shows a cross-section side view of a stage in the manufacturing process where a mold compound 306 is placed on the RDL 304. In embodiments, the mold compound 306 may polymer materials, which may include filling compounds. In embodiments, the mold compound 306 at this stage may be a part of the cavity layer 308. In embodiments, the mold compound 306 and RDL 304 may be similar to mold compound 206 and RDL 204 of FIG. 2.

FIG. 3C shows a cross-section side view of a stage in the manufacturing process where a laser ablation process 324 may be applied to a surface of the mold compound 306 to form cavity 310 within the cavity layer 308. In embodiments, the laser ablation process 324 may result in sides 306a, 306b of the cavities 310 that may be substantially perpendicular to a plane of the RDL 304. In embodiments, the laser ablation process 324 may extend through to a surface of the RDL 304 and may expose bumps 312, which in embodiments may be electrical connectors with the RDL 304. Note that in embodiments, not all of the cavities 310 may expose bumps on the surface of the RDL 304.

FIG. 3D shows a cross-section side view of a stage in the manufacturing process, where FIG. 3C has been flipped, and the carrier 320 of FIG. 3A has been removed. Bumps 318 may be placed on the other surface of the RDL 304, and dies 316, which may be similar to dies 216 of FIG. 2, may be placed on the surface of the RDL 304. In embodiments, the dies 316 may be compute and/or network dies. In embodiments, a die 316 may be a plurality of dies that may be coupled with each other by a bridge (not shown).

FIG. 3E shows a cross-section side view of a stage in the manufacturing process, where FIG. 3D has been flipped, and HBM 330 may be inserted within the cavities 310 of FIG. 3C in the mold compound 306. In embodiments, the HBM 330 may be coupled with the RDL 304 using bumps 312 of FIG. 3C that are surrounded by underfill 313. In embodiments, the underfill 313 may be pre-applied prior to the attachment of the HBM 330. In embodiments, contacts 332 may be on the top of the HBM 330. In embodiments, the HBM 330 may be positioned not only to be in proximity with the dies 316, but also may be positioned in order to provide additional flexibility within the package shown in FIG. 3E. In embodiments, the HBM 330 may be placed using thermo-compression techniques or using laser bonding techniques. In embodiments, the bumps 312 may have a pitch of 40 μm or less, and in embodiments the corresponding pitch of the HBM 330 may have a pitch of 40 μm or less.

FIG. 3F shows a cross-section side view of an alternate stage in the manufacturing process where an HBM 330 is placed in one of the cavities 310 of FIG. 3C, and a silicon die 340 is placed in the other cavity. In embodiments, the silicon die 340 might not contain any circuitry (which may be referred to as a silicon dummy die). In embodiments, the composition of the material used within the silicon die 340 may be selected such that it has a CTE that is different from the CTE of the mold compound 306.

FIG. 3G shows a stage in the manufacturing process, following from the stage shown in FIG. 3E, where an underfill layer 336 is placed on top of the HBM 330 and on top of the cavity layer 308. A substrate 350 may be applied on the underfill 336 and may electrically couple with the HBM 330 using contacts 332 of FIG. 3E.

FIG. 3H shows a stage in the manufacturing process where the package shown in FIG. 3G has been flipped, and another underfill 338 is placed between the RDL 304 and the dies 316. FIG. 3I shows a stage in the manufacturing process where a thermal interface material (TIM) 344 is placed on top of the dies 316, and a heat sink 346 may be placed upon the TIM 344.

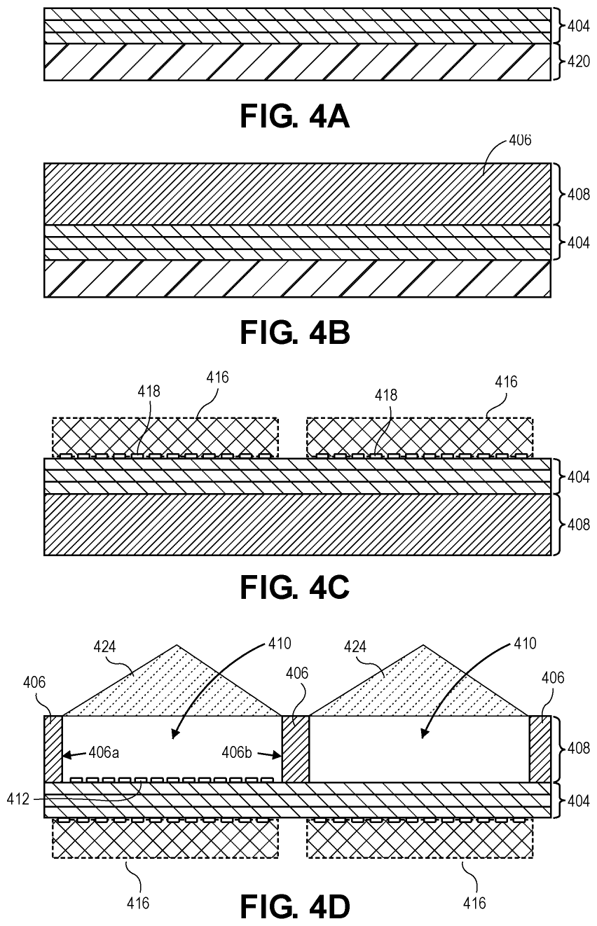

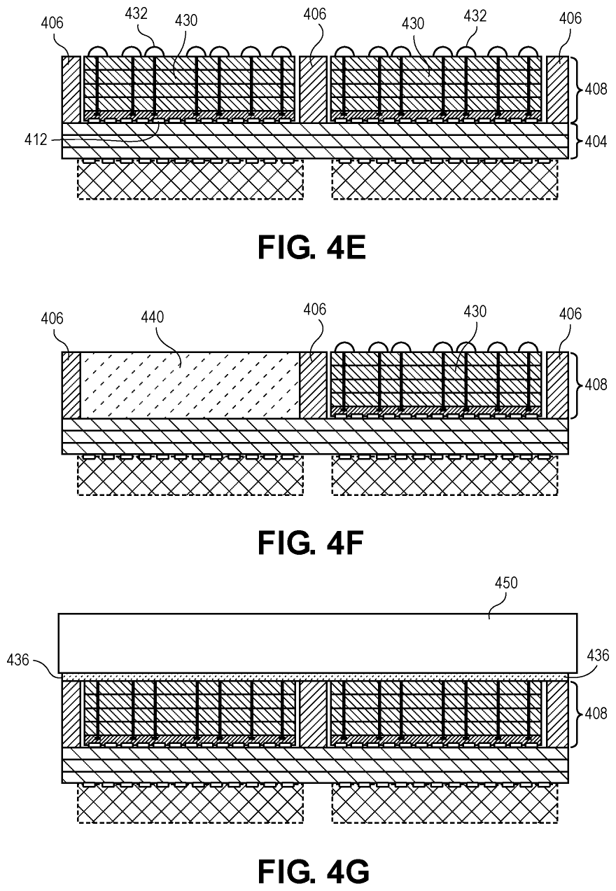

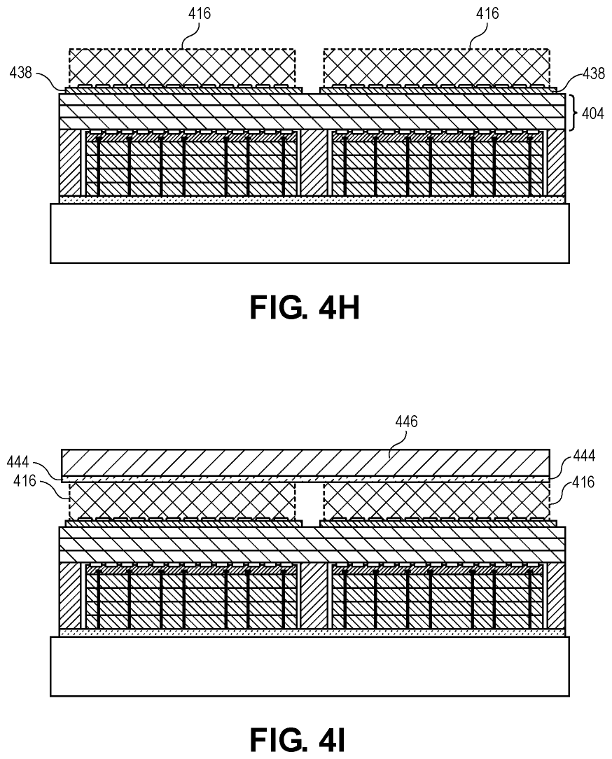

FIGS. 4A-4I illustrate side views of stages in another manufacturing process for placing dies within a formed cavity on a RDL, in accordance with various embodiments. In embodiments, FIGS. 4A-4I may illustrate a second mold compound ablation process. FIG. 4A shows a cross-section side view of a stage in the manufacturing process where a carrier 420 may be provided. In embodiments, the carrier 420 may be a glass carrier. In embodiments, a RDL 404 may be placed on the carrier 420. In embodiments, the RDL 404 may include a plurality of layers, as well as traces and/or vias (not shown) within the RDL 404. In embodiments, the RDL 404 may be similar to RDL 304 of FIG. 3A.

FIG. 4B shows a cross-section side view of a stage in the manufacturing process where a mold compound 406 is placed on the RDL 404. In embodiments, the mold compound 406 may be similar to mold compound 306 of FIG. 3B. In embodiments, the mold compound 406 at this stage may form the cavity layer 408.

FIG. 4C shows a cross-section side view of a stage in the manufacturing process, where the package of FIG. 4B has been flipped, and the carrier 420 of FIG. 4A has been removed. Bumps 418 have been put on the surface of the RDL 404, and dies 416, which may be similar to dies 216 of FIG. 2, may be placed on the surface of the RDL 404. In embodiments, the dies 416 may be compute and/or network dies. In embodiments, a die 416 may be a plurality of dies that may be coupled with each other by a bridge (not shown).

FIG. 4D shows a cross-section side view of a stage in the manufacturing process where a laser ablation process 424, which may be similar to the laser ablation process 324 of FIG. 3C, may be applied to a surface of the mold compound 406 to form cavity 410 within the cavity layer 408. In embodiments, the laser ablation process 424 may result in sides 406a, 406b of the cavities 410 that may be substantially perpendicular to a plane of the RDL 404. In embodiments, the laser ablation process 424 may extend through to a surface of the RDL 404 and expose bumps 412, which in embodiments may be electrical connectors with the RDL 404. Note that in embodiments, not all of the cavities 410 may expose bumps on the surface of the RDL 404.

FIG. 4E shows a cross-section side view of a stage in the manufacturing process, where an HBM 430 may be inserted within the cavities 410 of FIG. 4D in the mold compound 406. In embodiments, the HBM 430 may be coupled with the RDL 404 using bumps 412, and contacts 432 may be on the top of the HBM 430. In embodiments, the HBM 430 may be positioned not only to be in proximity with the dies 416, but they also may be positioned in order to provide additional flexibility within the package shown in FIG. 4E. In embodiments, the HBM 430, bumps 412, and contacts 432 may be similar to HBM 330, bumps 312, and contacts 332 of FIG. 3E.

FIG. 4F shows a cross-section side view of an alternate stage in the manufacturing process where an HBM 430 is placed in one of the cavities 410 of FIG. 4D, and a silicon die 440 is placed in the other cavity. In embodiments, the silicon die 440 might not contain any circuitry (which may be referred to as a silicon dummy die). In embodiments, the composition of the material used within the silicon die 440 may be selected such that it has a CTE that is different from the CTE of the mold compound 406.

FIG. 4G shows a stage in the manufacturing process, following from the stage shown in FIG. 4E, where the package of FIG. 4G has been flipped relative to FIG. 4E, and an underfill layer 436 may be placed on top of the HBM 430 and on top of the cavity layer 408. In embodiments, the underfill 436 may only partially expose the contacts 432, shown on FIG. 4E, that are on the HBM 430. A substrate 450 may be applied on the underfill 436 and may electrically couple with the HBM 430 on the cavity layer 408.

FIG. 4H shows a stage in the manufacturing process where the package shown in FIG. 4G has been flipped, and another underfill 438 is placed between the RDL 404 and the dies 416. FIG. 4I shows a stage in the manufacturing process where a thermal interface material (TIM) 444 is placed on top of the dies 416, and a heat sink 446 may be placed upon the TIM 444.

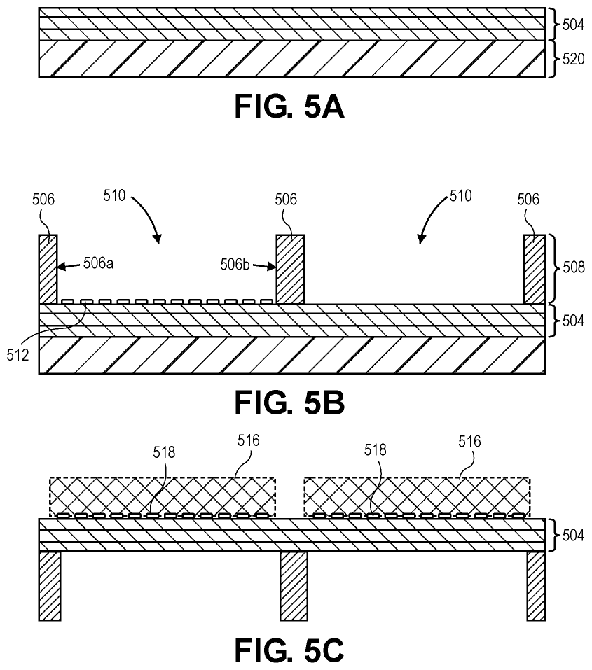

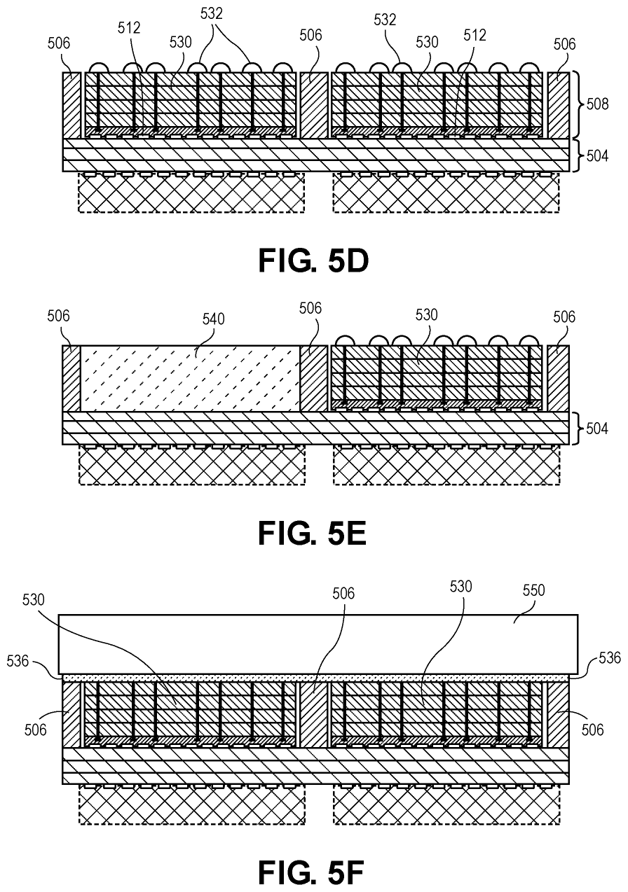

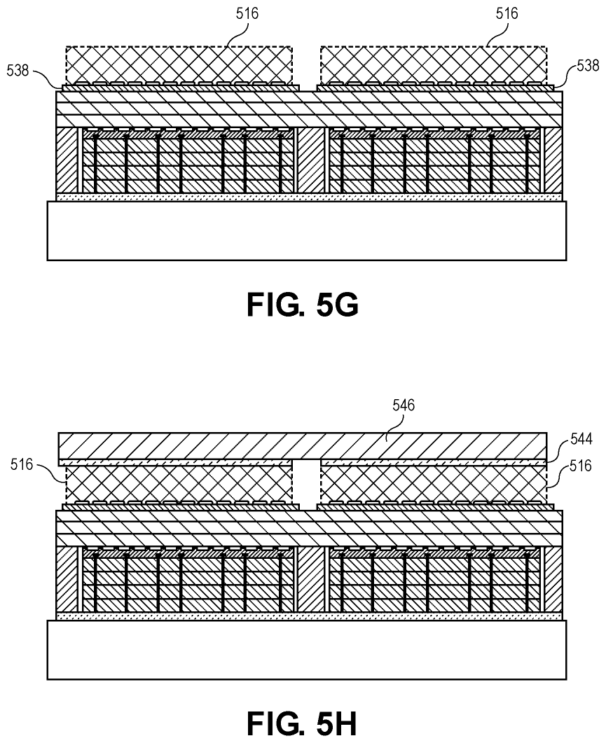

FIGS. 5A-5H illustrate side views of stages in another manufacturing process for placing dies within a formed cavity on a RDL, in accordance with various embodiments. In embodiments, FIGS. 5A-5H may illustrate a mold compound cavity process. FIG. 5A shows a cross-section side view of a stage in the manufacturing process where a carrier 520 may be provided. In embodiments, the carrier 520 may be a glass carrier. In embodiments, a RDL 504 may be placed on the carrier 520. In embodiments, the RDL 504 may include a plurality of layers, as well as traces and/or vias (not shown) within the RDL 504. In embodiments, the carrier 520 and the RDL 504 may be similar to carrier 420 and RDL 404 of FIG. 4A.

FIG. 5B shows a cross-section side view of a stage in the manufacturing process a mold compound 506, which may be similar to mold compound 406 of FIG. 4B, is built up to form cavity 510 within the cavity layer 508. In embodiments, the buildup process may result in sides 506a, 506b of the cavities 510 that may be substantially perpendicular to a plane of the RDL 504. In embodiments, the buildup process may expose bumps 512 on a surface of the RDL 504, which in embodiments may be electrical connectors with the RDL 504. Note that in embodiments, not all of the cavities 510 may expose bumps 512 on the surface of the RDL 504.

FIG. 5C shows a cross-section side view of a stage in the manufacturing process, where FIG. 5B has been flipped, and the carrier 520 of FIG. 5A has been removed. Bumps 518 have been put on the other surface of the RDL 504, and dies 516, which may be similar to dies 216 of FIG. 2, are placed on the surface of the RDL 504. In embodiments, the dies 516 may be compute and/or network dies. In embodiments, a die 516 may be a plurality of dies that may be coupled with each other by a bridge (not shown).

FIG. 5D shows a cross-section side view of a stage in the manufacturing process, where FIG. 5C has been flipped, and HBM 530 may be inserted within the cavities 510 of FIG. 5C in the mold compound 506. In embodiments, the HBM 530 may be coupled with the RDL 504 using bumps 512, and contacts 532 may be on the top of the HBM 530. In embodiments, the HBM 530 may be positioned not only to be in proximity with the dies 516, but they also may be positioned in order to provide additional flexibility within the package shown in FIG. 5D. In embodiments, the HBM 330 may be placed using thermo-compression techniques, or laser bonding techniques.

FIG. 5E shows a cross-section side view of an alternate stage in the manufacturing process where an HBM 530 is placed in one of the cavities 510 of FIG. 5C, and a silicon die 540 is placed in the other cavity. In embodiments, the silicon die 540 might not contain any circuitry (which may be referred to as a silicon dummy die). In embodiments, the composition of the material used within the silicon die 540 may be selected such that it has a CTE that is different from the CTE of the mold compound 506.

FIG. 5F shows a stage in the manufacturing process, following from the stage shown in FIG. 5D, where an underfill layer 536 is placed on top of the HBM 530 and on top of the cavity layer 508. In embodiments, the underfill 536 may only partially expose the contacts 532, shown on FIG. 5D, that are on the HBM 530. A substrate 550 may be applied on the underfill 536 and may electrically couple with the HBM 530.

FIG. 5G shows a stage in the manufacturing process where the package shown in FIG. 5F has been flipped, and another underfill 538 is placed between the RDL 504 and the dies 516. FIG. 5H shows a stage in the manufacturing process where a thermal interface material (TIM) 544 is placed on top of the dies 516, and a heat sink 546 may be placed upon the TIM 544.

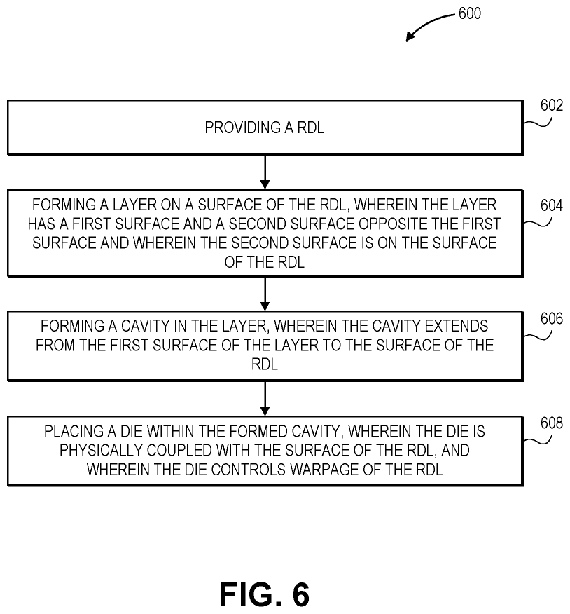

FIG. 6 illustrates an example of a process for creating a package that includes a RDL that have dies within cavities formed on the mold compound on the RDL, in accordance with various embodiments. Process 600 may be performed using the processes, systems, apparatus, and/or techniques described herein, and in particular with respect to FIGS. 1-5H.

At block 602, the process may include providing a redistribution layer (RDL). In embodiments, the RDL may be similar to RDL 104 of FIG. 1, RDL 204 of FIG. 2, RDL 304 of FIGS. 3A-3I, RDL 404 of FIGS. 4A-4I, or RDL 504 of FIGS. 5A-5H.

At block 604, the process may further include forming a layer on a surface of the RDL, wherein the layer has a first surface and a second surface opposite the first surface and wherein the second surface is on the surface of the RDL. In embodiments, the layer may be similar to mold compound 106 of FIG. 1, mold compound 206 of FIG. 2, mold compound 306 of FIGS. 3A-3I, mold compound 406 of FIGS. 4A-4I, or mold compound 506 of FIGS. 5A-5H. In some embodiments, the mold compound may be another layer of material or another structure, for example, a substrate.

At block 606, the process may further include forming a cavity in the layer, wherein the cavity extends from the first surface of the layer to the surface of the RDL. In embodiments, the cavity may be similar to cavity 110 of FIG. 1, cavity 210 of FIG. 2, cavity 310 of FIGS. 3A-3I, or cavity 410 of FIGS. 4A-4I.

At block 608, the process may further include placing a die within the formed cavity, wherein the die is physically coupled with the surface of the RDL, and wherein the die controls warpage of the RDL. In embodiments, the die may be similar to die 220 of FIG. 2, HBM 330 of FIGS. 3E-3I, die 340 of FIG. 3F, HBM 430 of FIGS. 4E-4I, or die 440 of FIG. 4F, HBM 530 of FIG. 5D-5H, or die 540 of FIG. 5E.

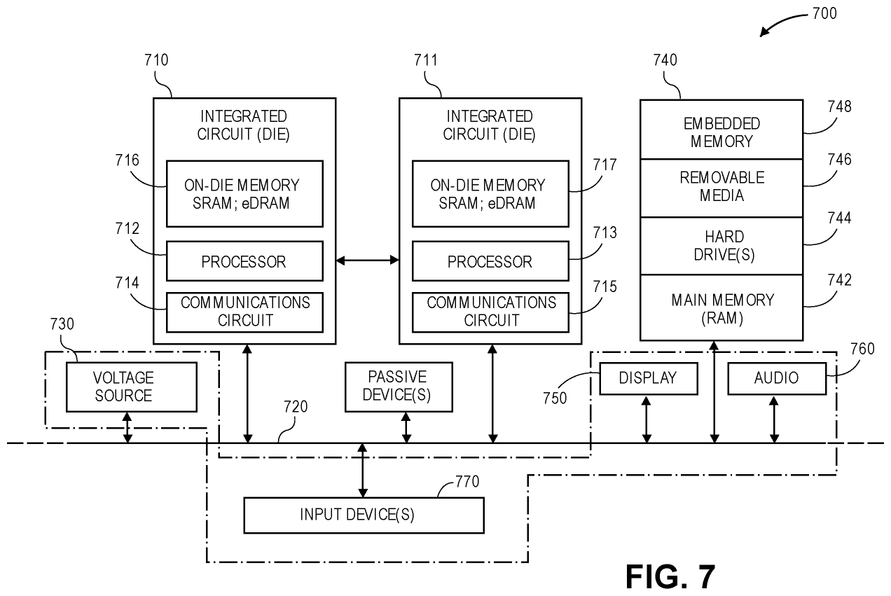

FIG. 7 is a schematic of a computer system 700, in accordance with an embodiment. The computer system 700 (also referred to as the electronic system 700) as depicted can embody die placement within a formed cavity on a redistribution layer, according to any of the several disclosed embodiments and their equivalents as set forth in this disclosure. The computer system 700 may be a mobile device such as a netbook computer. The computer system 700 may be a mobile device such as a wireless smart phone. The computer system 700 may be a desktop computer. The computer system 700 may be a hand-held reader. The computer system 700 may be a server system. The computer system 700 may be a supercomputer or high-performance computing system.

In an embodiment, the electronic system 700 is a computer system that includes a system bus 720 to electrically couple the various components of the electronic system 700. The system bus 720 is a single bus or any combination of busses according to various embodiments. The electronic system 700 includes a voltage source 730 that provides power to the integrated circuit 710. In some embodiments, the voltage source 730 supplies current to the integrated circuit 710 through the system bus 720.

The integrated circuit 710 is electrically coupled to the system bus 720 and includes any circuit, or combination of circuits according to an embodiment. In an embodiment, the integrated circuit 710 includes a processor 712 that can be of any type. As used herein, the processor 712 may mean any type of circuit such as, but not limited to, a microprocessor, a microcontroller, a graphics processor, a digital signal processor, or another processor. In an embodiment, the processor 712 includes, or is coupled with, die placement within a formed cavity on a redistribution layer, as disclosed herein. In an embodiment, SRAM embodiments are found in memory caches of the processor. Other types of circuits that can be included in the integrated circuit 710 are a custom circuit or an application-specific integrated circuit (ASIC), such as a communications circuit 714 for use in wireless devices such as cellular telephones, smart phones, pagers, portable computers, two-way radios, and similar electronic systems, or a communications circuit for servers. In an embodiment, the integrated circuit 710 includes on-die memory 716 such as static random-access memory (SRAM). In an embodiment, the integrated circuit 710 includes embedded on-die memory 716 such as embedded dynamic random-access memory (eDRAM).

In an embodiment, the integrated circuit 710 is complemented with a subsequent integrated circuit 711. Useful embodiments include a dual processor 713 and a dual communications circuit 715 and dual on-die memory 717 such as SRAM. In an embodiment, the dual integrated circuit 710 includes embedded on-die memory 717 such as eDRAM.

In an embodiment, the electronic system 700 also includes an external memory 740 that in turn may include one or more memory elements suitable to the particular application, such as a main memory 742 in the form of RAM, one or more hard drives 744, and/or one or more drives that handle removable media 746, such as diskettes, compact disks (CDs), digital variable disks (DVDs), flash memory drives, and other removable media known in the art. The external memory 740 may also be embedded memory 748 such as the first die in a die stack, according to an embodiment.

In an embodiment, the electronic system 700 also includes a display device 750, an audio output 760. In an embodiment, the electronic system 700 includes an input device such as a controller 770 that may be a keyboard, mouse, trackball, game controller, microphone, voice-recognition device, or any other input device that inputs information into the electronic system 700. In an embodiment, an input device 770 is a camera. In an embodiment, an input device 770 is a digital sound recorder. In an embodiment, an input device 770 is a camera and a digital sound recorder.

As shown herein, the integrated circuit 710 can be implemented in a number of different embodiments, including a package substrate having die placement within a formed cavity on a redistribution layer, according to any of the several disclosed embodiments and their equivalents, an electronic system, a computer system, one or more methods of fabricating an integrated circuit, and one or more methods of fabricating an electronic assembly that includes a package substrate having die placement within a formed cavity on a redistribution layer, according to any of the several disclosed embodiments as set forth herein in the various embodiments and their art-recognized equivalents. The elements, materials, geometries, dimensions, and sequence of operations can all be varied to suit particular I/O coupling requirements including array contact count, array contact configuration for a microelectronic die embedded in a processor mounting substrate according to any of the several disclosed package substrates having die placement within a formed cavity on a redistribution layer embodiments and their equivalents. A foundation substrate may be included, as represented by the dashed line of FIG. 7. Passive devices may also be included, as is also depicted in FIG. 7.

Although certain embodiments have been illustrated and described herein for purposes of description, a wide variety of alternate and/or equivalent embodiments or implementations calculated to achieve the same purposes may be substituted for the embodiments shown and described without departing from the scope of the present disclosure. This application is intended to cover any adaptations or variations of the embodiments discussed herein. Therefore, it is manifestly intended that embodiments described herein be limited only by the claims.

Where the disclosure recites “a” or “a first” element or the equivalent thereof, such disclosure includes one or more such elements, neither requiring nor excluding two or more such elements. Further, ordinal indicators (e.g., first, second or third) for identified elements are used to distinguish between the elements, and do not indicate or imply a required or limited number of such elements, nor do they indicate a particular position or order of such elements unless otherwise specifically stated.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope is to be determined entirely by the following claims, which are to be construed in accordance with established doctrines of claim interpretation.

### Examples

The following paragraphs describe examples of various embodiments.

Example 1 is an apparatus comprising: a redistribution layer (RDL); a layer on a first surface of the RDL, wherein the layer has a top surface and a bottom surface opposite the top surface, and wherein the bottom surface of the layer is on a top of the RDL; a cavity in the layer, wherein the cavity extends from the top surface of the layer to the first surface of the RDL; and wherein sides of the cavity are planar and are substantially perpendicular to a plane of the RDL.

Example 2 includes the apparatus of example 1, wherein the layer is a selected one of: a mold compound, a silicon block, or a substrate.

Example 3 includes the apparatus of examples 1 or 2, wherein the top of the RDL includes electrical connections.

Example 4 includes the apparatus of examples 1, 2, or 3, further comprising a die in the cavity, wherein the die is physically coupled with the top of the RDL.

Example 5 includes the apparatus of example 4, wherein the die is a selected one of: a silicon die or a dummy die.

Example 6 includes the apparatus of examples 4 or 5, wherein the die is a high bandwidth memory die (HBM), HBM is electrically coupled with a top of the RDL through a plurality of connectors, and wherein the plurality of connectors have a pitch of less than 40 μm.

Example 7 includes the example of 6, further comprising an underfill between the die and the top of the RDL.

Example 8 includes the apparatus of examples 4, 5, 6, or 7, wherein the layer has a first coefficient of thermal expansion (CTE) and wherein the die has a second CTE, and wherein the first CTE is different than the second CTE.

Example 9 includes the apparatus of examples 1, 2, 3, 4, 5, 6, 7, or 8, wherein the cavity is a first cavity; and further comprising a second cavity in the layer, wherein the second cavity extends from the top surface of the layer to the top of the RDL.

Example 10 includes the apparatus of example 9, wherein the first cavity includes a first die that is directly physically coupled with the top of the RDL, wherein the second cavity includes a second die that is directly physically coupled with the top of the RDL, and wherein the first die and the second die provide structural rigidity for the apparatus or provide control warpage for the apparatus.

Example 11 is a package comprising: a redistribution layer (RDL); a layer on a top surface of the RDL, wherein the layer has a first side and a second side opposite the first side, and wherein the second side of the layer is on the top surface of the RDL; a plurality of cavities in the layer, wherein each of the plurality of cavities extend from the first side of the layer to the top surface of the RDL; a first plurality of dies, wherein each of the first plurality of dies is in a corresponding cavity and is physically coupled to the top surface of the RDL; and a second plurality of dies, wherein the second plurality of dies are on a bottom surface of the RDL that is opposite the top surface of the RDL, and wherein the second plurality of dies are electrically coupled with the bottom surface of the RDL.

Example 12 includes the package of example 11, wherein the first plurality of dies are high bandwidth memory dies (HBM), and wherein the HBM have a pitch of 40 μm or less.

Example 13 includes the package of examples 11 or 12, wherein sides of each of the plurality of cavities are substantially perpendicular to a plane of the RDL.

Example 14 includes the package of examples 11, 12, or 13, wherein the first plurality of dies are silicon dummy dies.

Example 15 includes the package of examples 11, 12, 13, or 14, wherein no portion of the layer is between at least one of the first plurality of dies and the top surface of the RDL.

Example 16 includes the package of examples 11, 12, 13, 14, or 15, further comprising an underfill at least one of the first plurality of dies and the top surface of the RDL.

Example 17 includes the package of examples 11, 12, 13, 14, 15, or 16, wherein the first plurality of dies provide structural rigidity for the package or provide control warpage for the package.

Example 18 is a method comprising: providing a redistribution layer (RDL); forming a layer on a surface of the RDL, wherein the layer has a first surface and a second surface opposite the first surface and wherein the second surface is on the surface of the RDL; forming a cavity in the layer, wherein the cavity extends from the first surface of the layer to the surface of the RDL; and placing a die within the formed cavity, wherein the die is physically coupled with the surface of the RDL, and wherein the die controls warpage of the RDL.

Example 19 includes the method of example 18, wherein the die is a high bandwidth memory die (HBM), wherein the HBM includes a plurality of electrical connectors on a side of the die, wherein the plurality of electrical connectors directly electrically couple with the surface of the RDL, and wherein a pitch of the electrical connectors is 40 μm or less.

Example 20 includes the method of examples 18 or 19, wherein the cavity is a plurality of cavities, and wherein the die is a plurality of dies, with each of the plurality of dies is placed within a corresponding one plurality of cavities.

What is claimed is:

1. An apparatus comprising:
a redistribution layer (RDL);
a layer on a first surface of the RDL, wherein the layer has a top surface and a bottom surface opposite the top surface, and wherein the bottom surface of the layer is on a top of the RDL;
a cavity in the layer, wherein the cavity extends from the top surface of the layer to the first surface of the RDL; and
wherein sides of the cavity are planar and are substantially perpendicular to a plane of the RDL.

2. The apparatus of claim 1, wherein the layer is a selected one of: a mold compound, a silicon block, or a substrate.

3. The apparatus of claim 1, wherein the top of the RDL includes electrical connections.

4. The apparatus of claim 1, further comprising a die in the cavity, wherein the die is physically coupled with the top of the RDL.

5. The apparatus of claim 4, wherein the die is a selected one of: a silicon die or a dummy die.

6. The apparatus of claim 4, wherein the die is a high bandwidth memory die (HBM), HBM is electrically coupled with a top of the RDL through a plurality of connectors, and wherein the plurality of connectors have a pitch of less than 40 μm.

7. The apparatus of claim 6, further comprising an underfill between the die and the top of the RDL.

8. The apparatus of claim 4, wherein the layer has a first coefficient of thermal expansion (CTE) and wherein the die has a second CTE, and wherein the first CTE is different than the second CTE.

9. The apparatus of claim 1, wherein the cavity is a first cavity; and further comprising a second cavity in the layer, wherein the second cavity extends from the top surface of the layer to the top of the RDL.

10. The apparatus of claim 9, wherein the first cavity includes a first die that is directly physically coupled with the top of the RDL, wherein the second cavity includes a second die that is directly physically coupled with the top of the RDL, and wherein the first die and the second die provide structural rigidity for the apparatus or provide control warpage for the apparatus.

11. A package comprising:
a redistribution layer (RDL);
a layer on a top surface of the RDL, wherein the layer has a first side and a second side opposite the first side, and wherein the second side of the layer is on the top surface of the RDL;
a plurality of cavities in the layer, wherein each of the plurality of cavities extend from the first side of the layer to the top surface of the RDL;
a first plurality of dies, wherein each of the first plurality of dies is in a corresponding cavity and is physically coupled to the top surface of the RDL; and
a second plurality of dies, wherein the second plurality of dies are on a bottom surface of the RDL that is opposite the top surface of the RDL, and wherein the second plurality of dies are electrically coupled with the bottom surface of the RDL.

12. The package of claim 11, wherein the first plurality of dies are high bandwidth memory dies (HBM), and wherein the HBM have a pitch of 40 μm or less.

13. The package of claim 11, wherein sides of each of the plurality of cavities are substantially perpendicular to a plane of the RDL.

14. The package of claim 11, wherein the first plurality of dies are silicon dummy dies.

15. The package of claim 11, wherein no portion of the layer is between at least one of the first plurality of dies and the top surface of the RDL.

16. The package of claim 11, further comprising an underfill at least one of the first plurality of dies and the top surface of the RDL.

17. The package of claim 11, wherein the first plurality of dies provide structural rigidity for the package or provide control warpage for the package.

18. A method comprising:
providing a redistribution layer (RDL);
forming a layer on a surface of the RDL, wherein the layer has a first surface and a second surface opposite the first surface and wherein the second surface is on the surface of the RDL;
forming a cavity in the layer, wherein the cavity extends from the first surface of the layer to the surface of the RDL; and
placing a die within the formed cavity, wherein the die is physically coupled with the surface of the RDL, and wherein the die controls warpage of the RDL.

19. The method of claim 18, wherein the die is a high bandwidth memory die (HBM), wherein the HBM includes a plurality of electrical connectors on a side of the die, wherein the plurality of electrical connectors directly electrically couple with the surface of the RDL, and wherein a pitch of the electrical connectors is 40 μm or less.

20. The method of claim 18, wherein the cavity is a plurality of cavities, and wherein the die is a plurality of dies, with each of the plurality of dies is placed within a corresponding one plurality of cavities.
